(19) United States
(12) Patent Application Publication
(10) Pub. No.: US 2015/0091134 A1
(43) Pub. Date: Apr. 2, 2015

(54) ATOMIC LAYER DEPOSITION

(71) Applicant: Dyson Technology Limited, Wiltshire (GB)

(72) Inventors: Gehan Anjil Joseph Amaratunga, Cambridge (GB); Youngjin Choi, Cambridge (GB); Sai Giridhar Shivareddy, Cambridge (GB); Nathan Charles Brown, Swindon (GB); Charles Anthony Neild Collis, Cirencester (GB)

(73) Assignee: Dyson Technology Limited, Wiltshire (GB)

(21) Appl. No.: 14/390,720

(22) PCT Filed: Apr. 3, 2013
(86) PCT No.: PCT/GB2013/050873

§ 371 Date: Oct. 3, 2014

(30) Foreign Application Priority Data
Apr. 5, 2012 (GB) 1206096.8

(51) Int. Cl. H01L 49/02; H01L 21/02; C23C 16/06; C23C 16/455; C23C 16/52

(52) U.S. Cl. CPC H01L 28/40; C23C 16/455; C23C 16/52; C23C 16/06; H01L 21/02181; H01L 21/02186; H01L 21/0228
USPC 257/532; 428/701; 438/785

(57) ABSTRACT

A method of depositing a material on a substrate using an atomic layer deposition process, wherein the deposition process comprises a first deposition step, a second deposition step subsequent to the first deposition step, and a delay of at least one minute between the first deposition step and the second deposition step. Each deposition step comprises a plurality of deposition cycles. The delay is introduced to the deposition process by prolonging a period of time for which a purge gas is supplied to a process chamber housing the substrate at the end of a selected one of the deposition cycles.

### REFERENCE TO RELATED APPLICATIONS

This application is a national stage application under 35 USC 371 of International Application No. PCT/GB2013/050873, filed Apr. 3, 2013, which claims the priority of United Kingdom Application No. 1206096.8, filed Apr. 5, 2012, the entire contents of which are incorporated herein by reference.

### FIELD OF THE INVENTION

This invention relates to a method of coating a substrate using atomic layer deposition.

### BACKGROUND OF THE INVENTION

Atomic layer deposition (ALD) is a thin film deposition technique whereby a given amount of material is deposited during each deposition cycle. Thus it is easy to control coating thickness. One downside is the speed at which a coating is built up.

ALD is based on sequential deposition of individual or fractional monolayers of a material. The surface on which the film is to be deposited is sequentially exposed to different precursors followed by purging of the growth reactor so as to remove any residual chemically active source gas or by products. When the growth surface is exposed to a precursor, it gets completely saturated by a monolayer of that precursor. The thickness of a monolayer depends on the reactivity of that precursor with the growth surface. This results in a number of advantages such as excellent conformality and uniformity, and easy and accurate film thickness control.

Two types of ALD are thermal and plasma enhanced (PEALD). ALD is very similar to chemical vapour deposition (CVD) based on binary reaction. A recipe for ALD is to find a CVD process based on binary reaction and then to apply two different kinds of reactants individually and sequentially. In ALD, the reactions occur spontaneously at various temperatures and will be referred to as thermal ALD because it can be performed without the aid of plasma or radical assistance. Single-element films are difficult to deposit using thermal ALD processes but can be deposited using plasma or radical-enhanced ALD. Thermal ALD tends to be faster and produce films with a better aspect ratio, and so it is known to combine thermal ALD and PEALD processes. The radicals or other energetic species in the plasma help to induce reactions that are not possible using just thermal energy. In addition to single-element materials, compound materials can also be deposited using plasma ALD. One important advantage is that plasma ALD can deposit films at much lower temperature than thermal ALD. Oxygen plasma ALD also can deposit metal oxides conformally on a hydrophobic surface.

In ALD, the growth of a film takes place in a cyclic fashion. Referring to FIG. 18, in the simplest case, one cycle consists of four stages. At the start of the process, the chamber is at a base vacuum 600 then, throughout the whole deposition process, an inert gas (Argon or Nitrogen) flow is introduced constantly into the deposition chamber building a constant base pressure 610. This gas flow also acts as purge gas in the purge cycles. The deposition cycle is as follows:
(i) Exposure of the first precursor 620, causing a sharp peak in pressure within the deposition chamber;
(ii) Purge by gas flow 630, or evacuation of the reaction chamber;
(iii) Exposure of the second precursor 640, causing a sharp peak in pressure within the deposition chamber; and
(iv) Purge or evacuation 650.

The deposition cycle is repeated as many times as necessary to obtain the desired film thickness.

### SUMMARY OF THE INVENTION

According to a first aspect, the present invention provides a method of depositing a material on a substrate, comprising the steps of providing a substrate and depositing a coating on to the substrate using atomic layer deposition, wherein the deposition comprises a first deposition step, a pause in the deposition, followed by a second deposition step.

A deposition step comprises a plurality of deposition cycles. Each deposition cycle includes all the deposition stages required to make a layer of the coating. For example to produce an oxide, each deposition cycle includes one or more deposition stages for each of the metal precursor and the oxidising precursor as an example, for the production of hafnium oxide there is one deposition stage for each of the hafnium and oxidising precursors. The coating can be considered to have been produced by two deposition steps separated by a pause or a delay. Thus, the coating is produced by completing a number of deposition cycles, pausing and then completing a second set comprising a number of deposition cycles.

The pause is a break or delay in the deposition process which has been found advantageous to certain properties of the material deposited on the substrate. The delay preferably has a duration of at least one minute. Thus, in a second aspect the present invention provides a method of depositing a material on a substrate using an atomic layer deposition process, wherein the deposition process comprises a first deposition step, a second deposition step subsequent to the first deposition step, and a delay for a period of time of at least one minute between the first deposition step and the second deposition step.

The delay or pause between a first and a second deposition step is unlike a purge or exposure stage. A purge has to be followed after every exposure stage to evacuate the deposition chamber whether one atomic layer (i.e. metal oxide) is formed or not. On the other hand, the delay occurs only after one complete atomic layer deposition and it interrupts or intervenes with continuous deposition process flow. Thus the delay can be distinguished from a purge stage as the delay is not one of stages in a deposition cycle. Likewise the delay can be distinguished from an exposure stage where reactants are introduced into the chamber as the pressure in this stage increases and additionally this is one of the stages in a deposition cycle. In addition, it is preferred that the temperature within the chamber is maintained during the delay or pause. Thus, the temperature conditions for the delay or pause are substantially similar to those of the deposition steps. The delay or pause is not a post deposition annealing step where the temperature of the final coated substrate is increased it is rather an intermediate step between two deposition steps or two sets of deposition cycles.

The delay is preferably introduced to the deposition by maintaining constant base pressure in a process chamber for example by maintaining a constant flow of Argon gas in the process chamber in which the substrate is located for a period of time of at least one minute between the first deposition step and the second deposition step, and so in a third aspect the present invention provides a method of depositing a material on a substrate using an atomic layer deposition process, wherein the deposition process comprises a first deposition step, a second deposition step subsequent to the first deposition step, and for a period of time between the first deposition step and the second deposition step maintaining a substantially constant pressure in the chamber.

The duration of said period of time is preferably at least one minute and preferably in the range from 1 minute to 120 minutes, more preferably in the range from 10 minutes to 90 minutes. Each deposition step preferably comprises a plurality of consecutive deposition cycles. Each of the deposition steps preferably comprise at least fifty deposition cycles, and at least one of the deposition steps may comprise at least one hundred deposition cycles. In one example, each of the deposition steps comprises two hundred consecutive deposition cycles. The duration of the delay between the deposition steps is preferably longer than the duration of each deposition cycle. The duration of each deposition cycle is preferably in the range from 40 to 50 seconds.

The delay between the deposition steps has a duration that is greater than any delay between consecutive deposition cycles. It is preferred that there is substantially no delay between consecutive deposition cycles, but in any event the introduction of a pause between deposition steps is in addition to any delay between consecutive deposition cycles. In the event that there is a delay of any duration between consecutive deposition cycles, the invention may be considered to be a selective increase in the delay between a selected two deposition cycles.

Each deposition cycle preferably commences with the supply of a precursor to a process chamber housing the substrate. Each deposition cycle preferably terminates with the supply of a purge gas to the process chamber.

Each deposition cycle preferably terminates with the introduction of the purge gas into the chamber for a second period of time which is shorter than the duration of the period of time between the first deposition step and the second deposition step. The delay between deposition steps may be considered to be provided by a prolonged duration of a period of time for which purge gas is supplied to the process chamber at the end of a selected one of the deposition cycles. This selected deposition cycle may occur towards the start of the deposition process, towards the end of the deposition cycle, or substantially midway through the deposition process.

In a fourth aspect, the present invention provides a method of depositing a material on a substrate, wherein a plurality of atomic layer deposition cycles are performed on a substrate located in a process chamber to deposit the coating on the substrate, each deposition cycle comprising introducing a plurality of precursors sequentially into the chamber, and, after introducing each precursor into the chamber, introducing a purge gas to the chamber for a period of time, and wherein, for a selected one of the deposition cycles performed before a final deposition cycle, the duration of the period of time for which purge gas is supplied to the chamber immediately prior to the commencement of the subsequent deposition cycle is greater than the duration of that period of time for each of the other deposition cycles. For the selected one of the deposition cycles, the duration of said period of time is preferably at least one minute, and is preferably in the range from 1 to 120 minutes. During said period of time between deposition cycles that is greater, the pressure of the purge gas is preferably substantially in the chamber.

At least one of the deposition cycles is preferably a plasma enhanced atomic layer deposition cycle.

Preferably the substrate is a structured substrate. For example, the substrate may comprise a plurality of carbon nanotubes (CNTs), each preferably having a diameter of around 50-60 nm. The structured substrate may be provided as a regular array or as a random array. Alternatively, the substrate may be a non-structured substrate.

The substrate may comprise silicon or CNTs. A thin film, or coating, formed by the deposition process is preferably a metal oxide, for example hafnium oxide or titanium oxide.

Each deposition cycle preferably comprises the steps of (i) introducing a precursor to a process chamber, (ii) purging the process chamber using a purge gas, (iii) introducing an oxygen source as a second precursor to the process chamber, and (iv) purging the process chamber using the purge gas. The oxygen source may be one of oxygen and ozone. The purge gas may be argon, nitrogen or helium. To deposit hafnium oxide, an alkylamino hafnium compound precursor may be used. Each deposition cycle is preferably performed with the substrate at the same temperature, which is preferably in the range from 200 to 300° C., for example 250° C. Each deposition step preferably comprises at least 100 deposition cycles. For example, each deposition step may comprise 200 deposition cycles to produce a hafnium oxide coating having a thickness in the range from 25 to 50 nm. Where the deposition cycle is a plasma enhanced deposition cycle, step (iii) above preferably also includes striking a plasma, for example from argon or from a mixture of argon and one or more other gases, such as nitrogen, oxygen and hydrogen, before the oxidizing precursor is supplied to the chamber.

The introduction of a pause or a delay in an ALD process has been found to be beneficial to the electrical properties of a deposited material. One of the electrical properties that has been found to be unexpectedly improved by the introduction of a pause or delay in the ALD process is the dielectric constant of an oxide material. Another electrical property that has been improved is the leakage current of the deposited material.

The deposition step may comprise a first deposition step of PEALD followed by a second deposition step of thermal ALD. Some substrates, such as CNTs are hydrophobic for such materials, thus it is preferred that PEALD with an oxygen precursor is used for at least some of the cycles.

A fifth aspect of the present invention provides a coated substrate made using the aforementioned method.

A sixth aspect of the present invention provides a capacitor comprising a coated substrate made using the aforementioned method.

Features described above in connection with the first aspect of the invention are equally applicable to each of the second to sixth aspects of the invention, and vice versa.

### BRIEF DESCRIPTION OF THE DRAWINGS

The invention will now be described by example with reference to the accompanying drawings, in which:

FIG. 1 is a graph of dielectric constant against voltage for a continuous and a discontinuous PEALD of hafnium oxide;

FIG. 2 is a graph of leakage current density against voltage for a continuous and a discontinuous PEALD of hafnium oxide;

FIG. 3 is a graph of dielectric constant against voltage for a continuous and a discontinuous PEALD of hafnium oxide using an alternate silicon substrate;

FIG. 4 is a graph of dielectric constant against voltage for a continuous and a discontinuous thermal ALD of hafnium oxide using the alternate silicon substrate;

FIG. 5 is a graph of dielectric constant against voltage to illustrate the effect of different pause lengths on the capacitance of a titanium oxide coating;

FIG. 6 is a graph of dissipation factor against voltage for a titanium oxide coating;

FIG. 7 is a graph of leakage current density against voltage to illustrate the effect of different pause lengths on capacitance for a titanium oxide coating;

FIG. 8 is a graph of refractive index against photon energy for different titanium dioxide dielectric layers;

FIG. 9 is a graph of capacitance against voltage for aluminium/hafnium oxide/silicon capacitors the hafnium oxide layer being produce by PEALD;

FIG. 10 is a graph of capacitance against voltage for an aluminium/hafnium oxide/silicon capacitor using the antimony doped silicon substrate the hafnium oxide layer being produce by thermal ALD;

FIG. 11a is a graph illustrating the relative permittivity of a hafnium oxide coating as a function of delay time;

FIG. 11b is a graph illustrating the fixed charge density (Q_{f}) of a hafnium oxide coating as a function of delay time;

FIG. 11c is a graph illustrating the variation of Δk and ΔQ_{f} of a hafnium oxide coating as a function of delay time;

FIG. 12 shows a TEM image of a continuous PEALD hafnium oxide coating;

FIGS. 13a and 13b show the hafnium oxide coating of FIG. 12 at higher magnification;

FIG. 14 shows a TEM image of a discontinuous PEALD hafnium oxide coating with a delay of 60 minutes;

FIGS. 15a and 15b show the hafnium oxide coating of FIG. 14 at higher magnification;

FIG. 16 shows the hafnium oxide coating of FIG. 14 at even higher magnification;

FIG. 17 shows a graph of leakage current density against electric field for PEALD produced hafnium oxide coatings to illustrate the effect of different pause lengths on the leakage current density of the hafnium oxide coating;

FIG. 18 shows schematically a graph of a thermal ALD process; and

FIG. 19 shows schematically a graph of a PEALD process.

### DETAILED DESCRIPTION OF THE INVENTION

The invention utilises an atomic layer deposition process to form a thin film or coating on a substrate. The following examples describe a method for forming a coating of a dielectric material on a substrate, which may be a high-k dielectric material used in transistor and capacitor fabrication. The atomic layer deposition process comprises a plurality of deposition cycles. In this example, each deposition cycle is a plasma enhanced atomic layer deposition (PEALD) cycle, which comprises the steps of (i) introducing a precursor to a process chamber, in which a substrate is located, (ii) purging the chamber with a purge gas to remove any excess precursor from the chamber and, (iii) striking a plasma within the chamber and supplying an oxidizing precursor to the chamber to react with precursor adsorbed on the surface of the substrate to form an atomic layer on the substrate, and (iv) purging the chamber with the purge gas to remove any excess oxidizing precursor from the chamber.

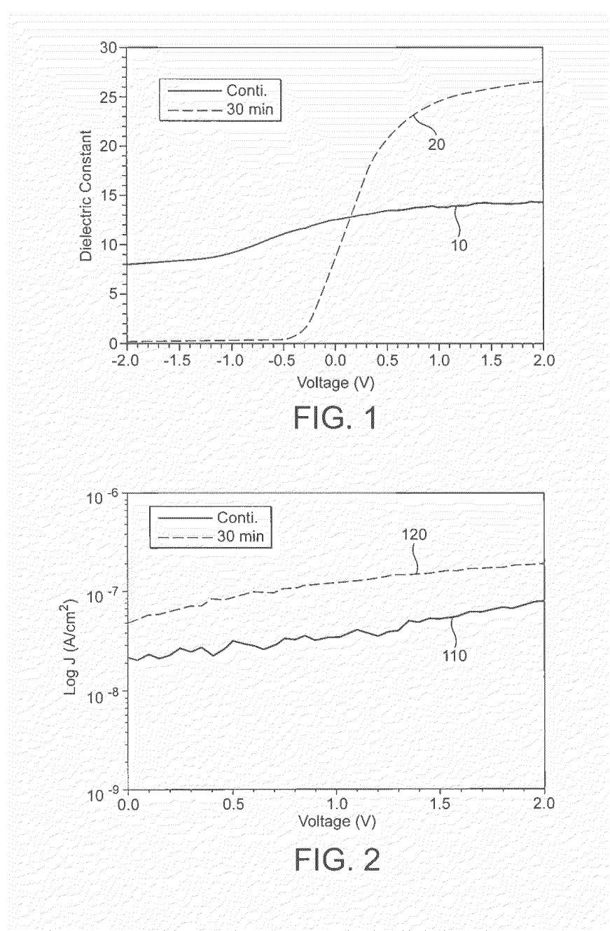

FIGS. 1, 2 and 3 are graphs illustrating the variation with voltage of dielectric constant and leakage current density respectively of two hafnium oxide coatings each deposited using PEALD onto a respective silicon substrate.

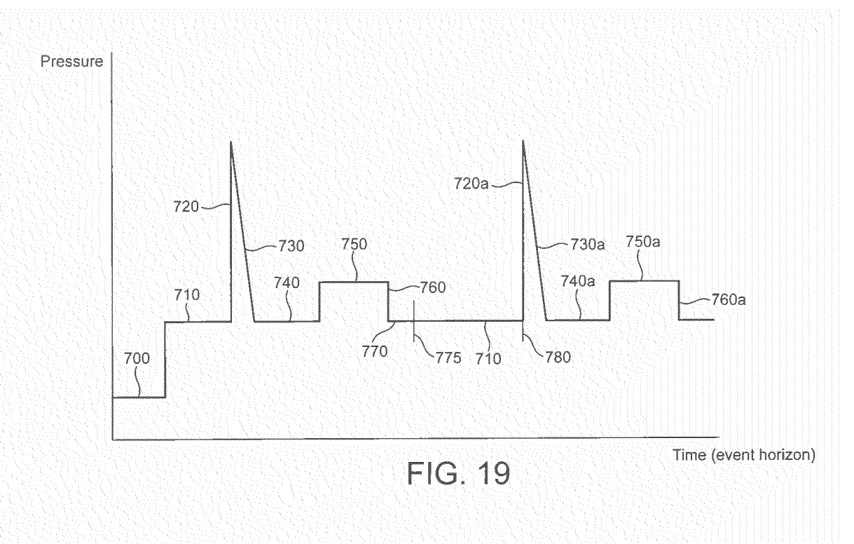

Each PEALD process was conducted using a Cambridge Nanotech Fiji 200 plasma ALD system. Referring also to FIG. 19, the substrate was located in a process chamber of the ALD system which was evacuated 700 to a pressure in the range from 0.3 to 0.5 mbar during the deposition process, and the substrate was held at a temperature of around 250° C. during the deposition process. Argon was selected as a purge gas, and was supplied to the chamber 710 at a flow rate of 200 sccm for a period of at least 30 seconds prior to commencement of the first deposition cycle.

Each deposition cycle commences with a supply of a hafnium precursor 720, 720a to the deposition chamber. The hafnium precursor was tetrakis dimethyl amino hafnium (TDMAHf, Hf(N(CH₃)₂)₄). The hafnium precursor was added to the purge gas for a period of 0.25 seconds. Following the introduction of the hafnium precursor to the chamber, the argon gas flow purged 730, 730a for a further 5 seconds to remove any excess hafnium precursor from the chamber. A plasma was then struck 740, 740a using the argon purge gas. The plasma power level was 300 W. The plasma was stabilised for a period of 5 seconds before oxygen was supplied 750, 750a to the plasma at a flow rate of 20 sccm for a duration of 20 seconds. The plasma power was switched off and the flow of oxygen stopped, and the argon gas flow purged 760, 760a for a further 5 seconds to remove any excess oxidizing precursor from the chamber, and to terminate the deposition cycle.

Each coating was formed using a different respective deposition process. The first deposition process was a standard PEALD process comprising 400 consecutive deposition cycles, with substantially no delay between the end of one deposition cycle and the start of the next deposition cycle. The second deposition process was a discontinuous PEALD process, comprising a first deposition step, a second deposition step, and a delay between the first deposition step and the second deposition step. The first deposition step comprised 200 consecutive deposition cycles, again with substantially no delay between the end of one deposition cycle and the start of the next deposition cycle. The second deposition step comprised further 200 consecutive deposition cycles, again with substantially no delay between the end of one deposition cycle and the start of the next deposition cycle. The delay between the end of the final deposition cycle 775 of the first deposition step and the start 780 of the first deposition cycle of the second deposition step was 30 minutes. During the delay, the pressure in the chamber was maintained 710a in the range from 0.3 to 0.5 mbar, the substrate was held at a temperature of around 250° C., and the argon purge gas was conveyed continuously to the chamber at 200 sccm. This delay between the deposition steps may also be considered to be an increase in the period of time during which purge gas is supplied to the chamber at the end of a selected deposition cycle. The thicknesses of coatings produced by both deposition processes were around 36 nm.

With reference to FIG. 1, the variation in dielectric constant with voltage for the standard PEALD process is indicated at 10, whereas the variation in dielectric constant with voltage for the discontinuous PEALD process is indicated at 20. The discontinuous process produced a coating having a dielectric constant with a value of 26 at 2V. The silicon substrate used for these examples was a silicon wafer that was doped with arsenic and had a resistivity of 0.005 ohm cm.

FIG. 2 illustrates the variation in leakage current density with voltage for the same hafnium oxide coatings. The variation in the leakage current density of the coating formed using the continuous process is indicated at 110, whereas the variation in the leakage current density of the coating formed using the discontinuous process is indicated at 120. The leakage current of the coating formed using the conventional continuous process was lower than that formed using the discontinuous process.

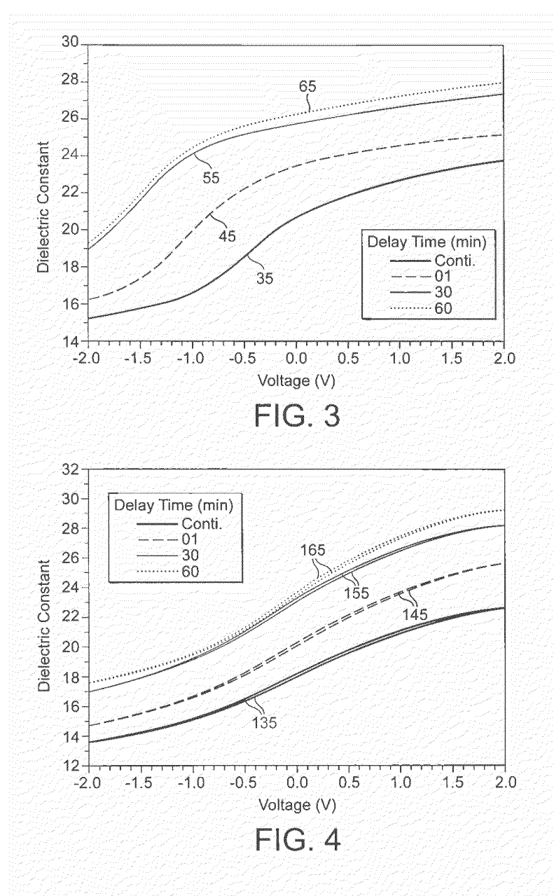

FIG. 3 shows the effect of different delay durations on the dielectric constant of a hafnium oxide coating on a different silicon substrate to that used with respect to FIGS. 1 and 2. In this example the silicon was a silicon wafer doped with antimony and had a resistivity of 0.1 ohm cm. The PEALD process was carried out under the same conditions as FIGS. 1 and 2 however, in addition to a continuous process 35, and one with a thirty minute delay 55, further experiments were carried out with a delay of one minute 45 and sixty minutes 65 after 200 cycles. With this more optimised silicon substrate, the dielectric constant between −2 and +2v for the coatings with a delay are consistently higher than for the continuous or standard process. The improvement increases with delay time however, the benefit is non-linear. Thus, at 2v the continuous process produced a coating with a dielectric constant of 23; a one minute delay produced a coating with a dielectric constant of around 24; a thirty minute delay produced a coating with a dielectric constant of 27; and the sixty minute delay produced a coating with a dielectric constant of almost 28.

FIG. 4 is a graph illustrating the variation with voltage of dielectric constant of a hafnium oxide coating deposited using thermal ALD onto the antimony doped silicon substrate.

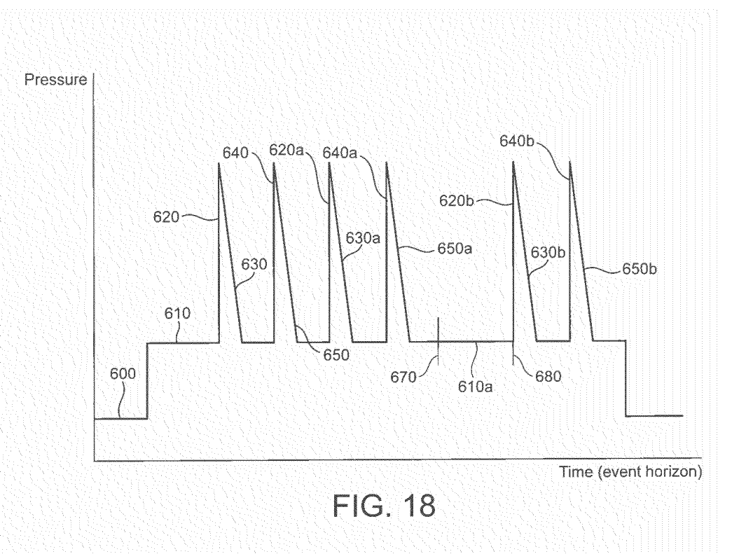

Each thermal ALD process was conducted using the Cambridge Nanotech Fiji 200 plasma ALD system. Referring now to FIG. 18, the substrate was located in a process chamber of the ALD system which was evacuated 600 to a pressure in the range from 0.3 to 0.5 mbar during the deposition process, and the substrate was held at a temperature of around 250° C. during the deposition process. Argon was selected as a purge gas, and was supplied to the chamber 610 at a flow rate of 200 sccm for a period of at least 30 seconds prior to commencement of the first deposition cycle.

Each deposition cycle commences with a supply of a hafnium precursor 620, 620a, 620b to the deposition chamber. The hafnium precursor was tetrakis dimethyl amino hafnium (TDMAHf, Hf(N(CH₃)₂)₄). The hafnium precursor was added to the purge gas for a period of 0.25 seconds. Following the introduction of the hafnium precursor to the chamber, the argon gas flow purged 630, 630a, 630b for a further 5 seconds to remove any excess hafnium precursor from the chamber. The second precursor, water was then introduced 640, 640a, 640b into the chamber for a period of 0.06 seconds. Then, the argon gas flow purged 650, 650a, 650b for a further 5 seconds to remove any excess oxidizing precursor from the chamber, and to terminate the deposition cycle.

Each coating was formed using a different respective deposition process. Referring now to FIGS. 4 and 18, the first deposition process was a standard thermal ALD process 135 comprising 400 consecutive deposition cycles, with substantially no delay between the end of one deposition cycle and the start of the next deposition cycle. The second deposition process was a discontinuous thermal ALD process, comprising a first deposition step, a second deposition step, and a delay between the first deposition step and the second deposition step. The first deposition step comprised 200 consecutive deposition cycles, again with substantially no delay between the end of one deposition cycle and the start of the next deposition cycle. The second deposition step comprised further 200 consecutive deposition cycles, again with substantially no delay between the end of one deposition cycle and the start of the next deposition cycle. The delay between the end of the final deposition cycle 670 of the first deposition step and the start 680 of the first deposition cycle of the second deposition step was one of 1, 30 and 60 minutes. During the delay, the pressure in the chamber was maintained 610a in the range from 0.3 to 0.5 mbar, the substrate was held at a temperature of around 250° C., and the argon purge gas was conveyed continuously to the chamber at 200 sccm. This delay between the deposition steps may also be considered to be an increase in the period of time during which purge gas is supplied to the chamber at the end of a selected deposition cycle. The thicknesses of coatings produced by both deposition processes were around 36 nm.

Referring to FIG. 18, the penultimate deposition cycle of the first deposition step 620, 630, 640, 650 is followed directly by the final deposition cycle of the first deposition step 620a, 630a, 640a, 650a. Then a delay 670 to 680 is introduced between the first and second deposition steps which according to the invention is preferably anywhere between 1 and 120 minutes and then a first cycle of the second deposition step 620b, 630b, 640b, 650b commences.

The graph of FIG. 4 shows the dielectric constant between −2 and +2v for the coatings with a delay are consistently higher than for the continuous or standard process. The improvement increases with delay time however, the benefit is non-linear. Thus, at 2v the continuous process produced a coating with a dielectric constant of 22; a one minute delay produced a coating with a dielectric constant of around 25; a thirty minute delay produced a coating with a dielectric constant of around 28; and the sixty minute delay produced a coating with a dielectric constant of 29.

Both the thermal and PEALD hafnium oxide coating produced on the antimony doped silicon substrate showed a similar improvement in dielectric constant when a pause was introduced into the ALD process. Thermal ALD has a slightly shorter cycle time as there is no plasma stage so for a given delay time thermal ALD is a more economical process.

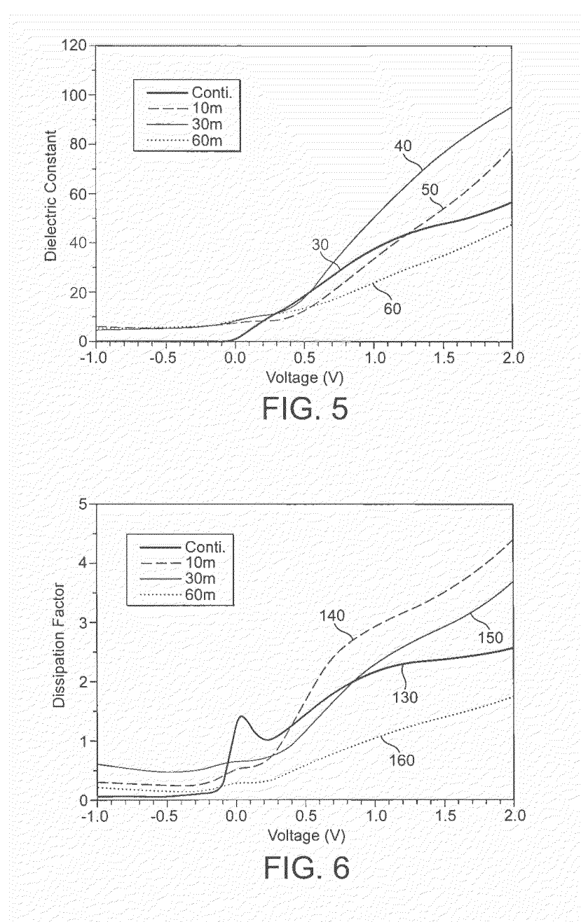

FIG. 5 shows the effect of different delay durations on the dielectric constant of a titanium oxide coating on a silicon substrate. The deposition cycle used to form the titanium oxide coating was the same as that described above, with the exception that the hafnium precursor was replaced by a titanium isopropoxide precursor.

Four titanium dioxide coatings were formed on respective silicon substrates, each using a different respective deposition process. The first deposition process was a standard PEALD process comprising 400 consecutive deposition cycles, with substantially no delay between the end of one deposition cycle and the start of the next deposition cycle, and the variation in dielectric constant of the resultant coating with voltage is indicated at 30 in FIG. 3. The second deposition process was a discontinuous PEALD process, comprising a first deposition step, a second deposition step, and a delay between the first deposition step and the second deposition step. The first deposition step comprised 200 consecutive deposition cycles, again with substantially no delay between the end of one deposition cycle and the start of the next deposition cycle. The second deposition step comprised further 200 consecutive deposition cycles, again with substantially no delay between the end of one deposition cycle and the start of the next deposition cycle. The delay between the final deposition cycle of the first deposition step and the first deposition cycle of the second deposition step was 10 minutes. During the delay, the pressure in the chamber was maintained in the range from 0.3 to 0.5 mbar, the substrate was held at a temperature of around 250° C., and the argon purge gas was conveyed to the chamber at 200 sccm. The variation in dielectric constant of the resultant coating with voltage is indicated at 40 in FIG. 3. The third deposition process was similar to the second deposition process, but with a delay of 30 minutes, and the variation in dielectric constant of the resultant coating with voltage is indicated at 50 in FIG. 3. The fourth deposition process was similar to the second deposition process, but with a delay of 60 minutes, and the variation in dielectric constant of the resultant coating with voltage is indicated at 60 in FIG. 3. At negative voltages the graphs for the discontinuous processes are very similar, and the dielectric constant is higher than the zero voltage level for the continuous deposition process. At positive voltage, the coating produced using the second deposition process had the highest dielectric constant.

FIG. 6 shows the variation in dissipation factor with voltage for these four titanium oxide coating. The variations in dissipation factor with voltage for the coatings produced using each of the first to fourth deposition processes are indicated respectively at 130, 140, 150 and 160 in FIG. 6. At negative voltage, a lower dissipation factor was observed for the coating produced using the standard deposition process.

The variation of dissipation factor for both PEALD and thermal ALD hafnium oxide coatings was investigated. In both cases the dissipation factor was near zero, less than 0.1 across the voltage range of −2 to +2v. This lower value is due to the fact that hafnium oxide has a very low leakage current so is a close to perfect dielectric with close to perfect capacitor behaviour.

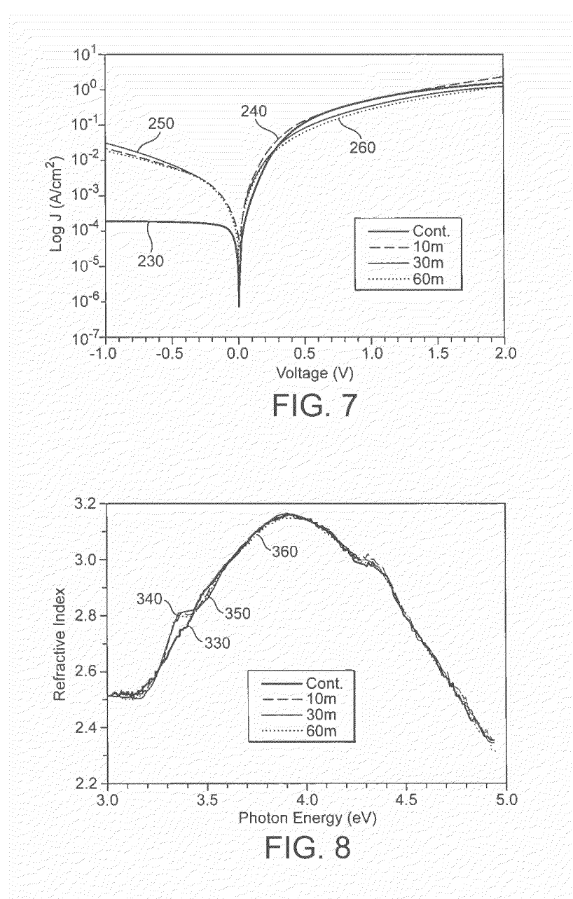

FIG. 7 shows the variation in leakage current densities with voltage for these four titanium oxide coatings. The variations in leakage current density with voltage for the coatings produced using each of the first to fourth deposition processes are indicated respectively at 230, 240, 250 and 260 in FIG. 7. At negative voltage, the lowest leakage current density was observed in the coating formed using the continuous first deposition process.

FIG. 8 shows the refractive indexes, using spectroscopic ellipsometry, for the four titanium oxide coatings. It is known for TiO₂ that the distinct two peak characteristic seen in the high-energy region (in ellipsometry) after exceeding band gap energy (˜3 eV) that is usually observed in semi-conducting Ga compounds, in epitaxial anatase phase. The reasons for the two peak characteristic are due to dense fine crystallinity of epitaxial anatase films. The refractive indexes of the coatings formed using the discontinuous second to fourth deposition processes, indicated at 340, 350, and 360 respective, show the two peak characteristics, whereas the refractive index of the coating formed using the continuous first deposition process, indicated at 330, shows only one peak.

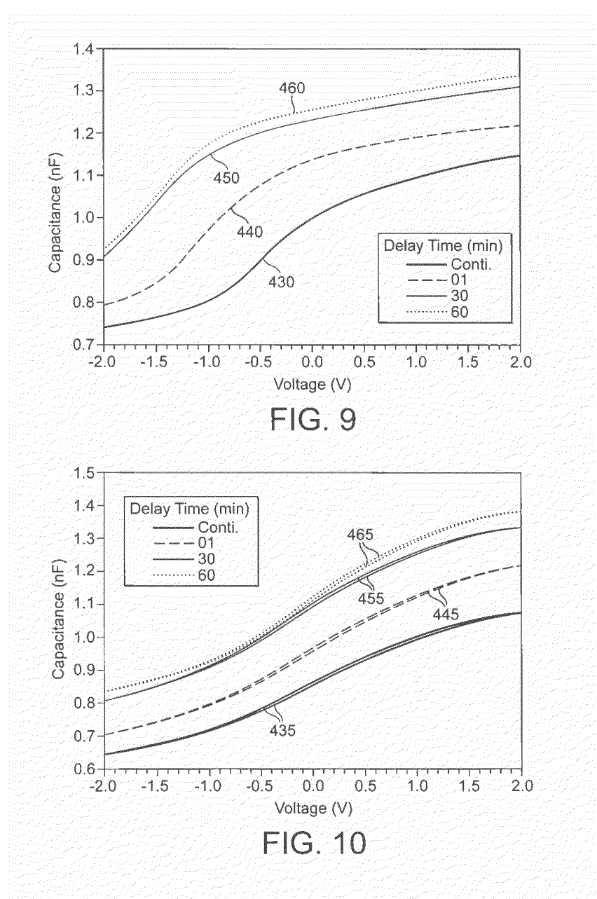

FIG. 9 shows the variation of capacitance with voltage for four different aluminium/hafnium oxide/silicon capacitors. Each metal-insulator-semiconductor (Al/HfO₂/n-Si) capacitor structure was made by applying dots of aluminum on top of the PEALD hafnium oxide coated antimony doped silicon substrate. The dots were 0.5 mm in diameter and were made by evaporation of aluminum. The four hafnium oxide-coated silicon substrates were formed using four different deposition processes. The first hafnium oxide-coated silicon substrate was formed using the first hafnium oxide deposition process described above with respect to FIGS. 1 to 3, and the variation with voltage of the capacitance of the capacitor formed using that coated substrate is indicated at 430 in FIG. 9. The second hafnium oxide-coated silicon substrate was formed using the second hafnium oxide deposition process described above, but with a delay having a duration of 1 minute instead of 10 minutes. The variation with voltage of the capacitance of the capacitor formed using that coated substrate is indicated at 440 in FIG. 9. The third hafnium oxide-coated silicon substrate was formed using the second hafnium oxide deposition process described above, but with a delay having a duration of 30 minutes instead of 10 minutes. The variation with voltage of the capacitance of the capacitor formed using that coated substrate is indicated at 450 in FIG. 9. The fourth hafnium oxide-coated silicon substrate was formed using the second hafnium oxide deposition process described above, but with a delay having a duration of 60 minutes instead of 10 minutes. The variation with voltage of the capacitance of the capacitor formed using that coated substrate is indicated at 460 in FIG. 9. The graphs illustrate that the capacitance-voltage characteristics of the four coatings show very little hysteresis and that the presence of the delay between the deposition steps provides an increase in the capacitance of the capacitor. The increase in capacitance is greatest for the coating formed using the fourth deposition process, but the variation in the capacitance gets smaller as the duration of the delay increases.

FIG. 10 is a graph of capacitance against voltage for an aluminium/hafnium oxide/silicon capacitor using the antimony doped silicon substrate.

Each metal-insulator-semiconductor (Al/HfO₂/n-Si) capacitor structure was made by applying dots of aluminum on top of the thermal ALD produced hafnium oxide coated antimony doped silicon substrate. The dots were 0.5 mm in diameter and were made by evaporation of aluminum. The four hafnium oxide-coated silicon substrates were formed using four different deposition processes. The first hafnium oxide-coated silicon substrate was formed using the first hafnium oxide deposition process described above with respect to FIG. 4, and the variation with voltage of the capacitance of the capacitor formed using that coated substrate is indicated at 435 in FIG. 10. The second hafnium oxide-coated silicon substrate was formed using the second hafnium oxide deposition process described above, but with a delay having a duration of 1 minute instead of 10 minutes. The variation with voltage of the capacitance of the capacitor formed using that coated substrate is indicated at 445 in FIG. 10. The third hafnium oxide-coated silicon substrate was formed using the second hafnium oxide deposition process described above, but with a delay having a duration of 30 minutes instead of 10 minutes. The variation with voltage of the capacitance of the capacitor formed using that coated substrate is indicated at 455 in FIG. 10. The fourth hafnium oxide-coated silicon substrate was formed using the second hafnium oxide deposition process described above, but with a delay having a duration of 60 minutes instead of 10 minutes. The variation with voltage of the capacitance of the capacitor formed using that coated substrate is indicated at 465 in FIG. 10. The graphs illustrate that the capacitance-voltage characteristics of the four coatings show very little hysteresis and that the presence of the delay between the deposition steps provides an increase in the capacitance of the capacitor. The increase in capacitance is greatest for the coating formed using the fourth deposition process, but the variation in the capacitance gets smaller as the duration of the delay increases.

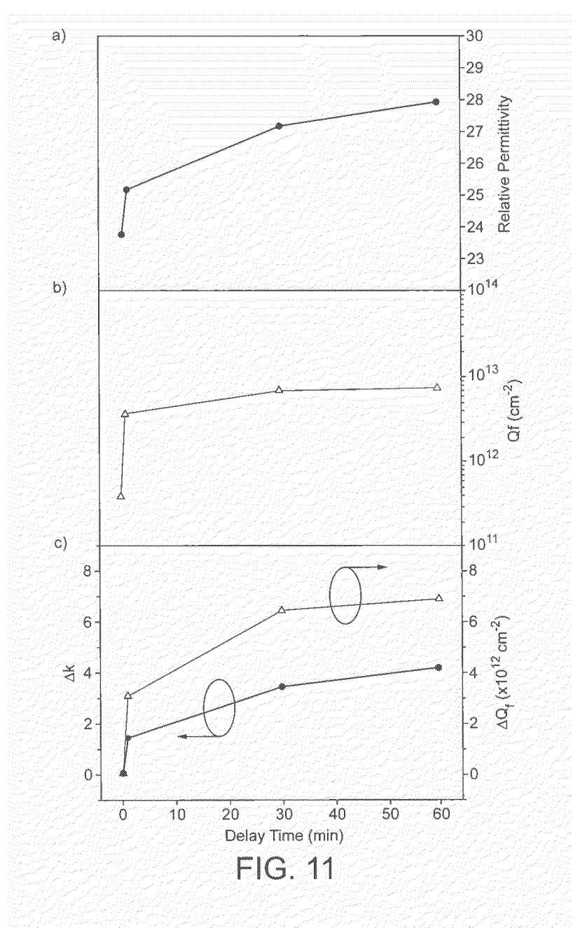

FIG. 11a shows a graph of the relative permittivity of the four capacitors discussed in relation to FIG. 9 i.e. formed with a PEALD hafnium oxide coating as a function of the duration of the delay. The values of relative permittivity were extracted from the accumulation region of the C-V curves. The relative permittivity increases with an increased duration of the delay. The same extraction was performed for the capacitors made using thermal ALD coated hafnium oxide and a similar graph was seen. FIG. 11b shows a graph of fixed charge density (Q_{f}) of the four capacitors as a function of the duration of the delay. During the delay in the deposition process, it is considered that oxygen vacancies (or defects) on the 200^{th} monolayer can be formed (as the HfO₂ coating was exposed to argon gas for a period of time) and this increases the fixed charge density. Again the capacitors produced with thermal ALD coated hafnium oxide showed the a similar increase in fixed charge density when a delay was introduced. FIG. 11c shows a graph of Δk(=k_{delay}−k_{conti.}) and ΔQ_{f}(=Q_{fdelay}−Q_{fconti.}) of the four different capacitors as a function of the duration of the delay. Although some structural defects were created, an interface state density between the 200 layers of HfO₂ formed during each of the deposition steps may be smaller than that of between HfO₂ and silicon. This may lead to micro-structural changes in the HfO₂ coating and result in a higher permittivity of HfO₂.

The next set of Figures show TEM images of different hafnium oxide coatings. All the images were taken using scanning transmission electron microscopy high annular dark field imaging (STEM-HAADF) where a small probe is rastered across the specimen and the electronic radiation emerging from the sample is collected over a small solid angle in the far-field (Fraunhofer diffraction plane). Image intensity increases with specimen thickness, atomic number or density. Two microscopes were used for this investigation. An FEI Titan3 operated at 300 kV and an aberration corrector in the probe forming lens allowed an illumination angle of 18 milliradians, giving a (diffraction limited) probe size of 0.7 \acute{Å}. However, with the finite probe current (80 pA) this increases to about 0.92 \acute{Å}. Measurements here indicate transfer out to 1.02 \acute{Å}, i.e. about 10% broader than expected. Finally, a non-aberration corrected STEM (FEI Tecnai F20ST) was used for energy dispersive X-ray mapping. The probe size here was much broader: about 1 nm with a 1.3 nA probe current.

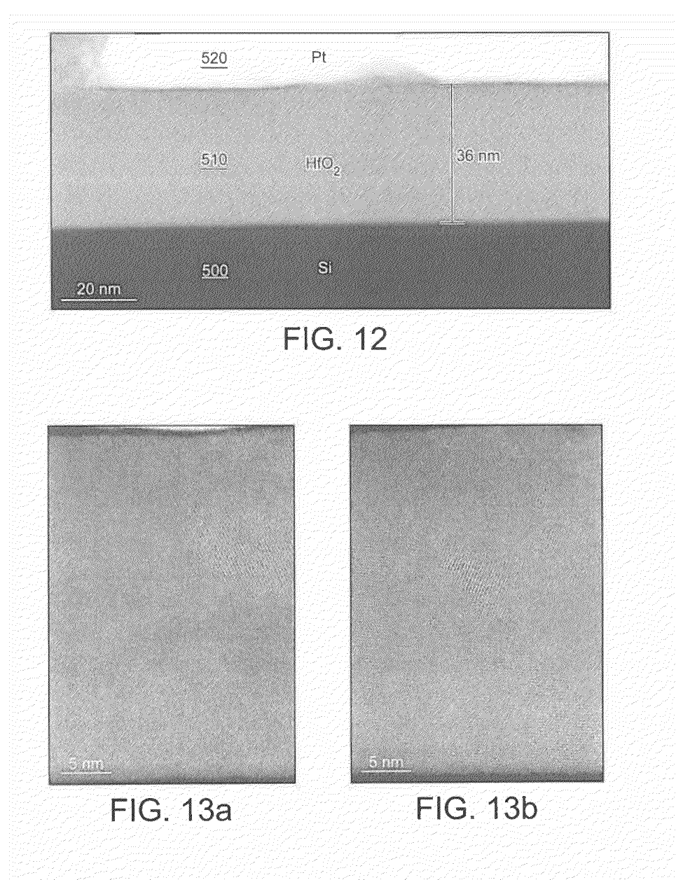

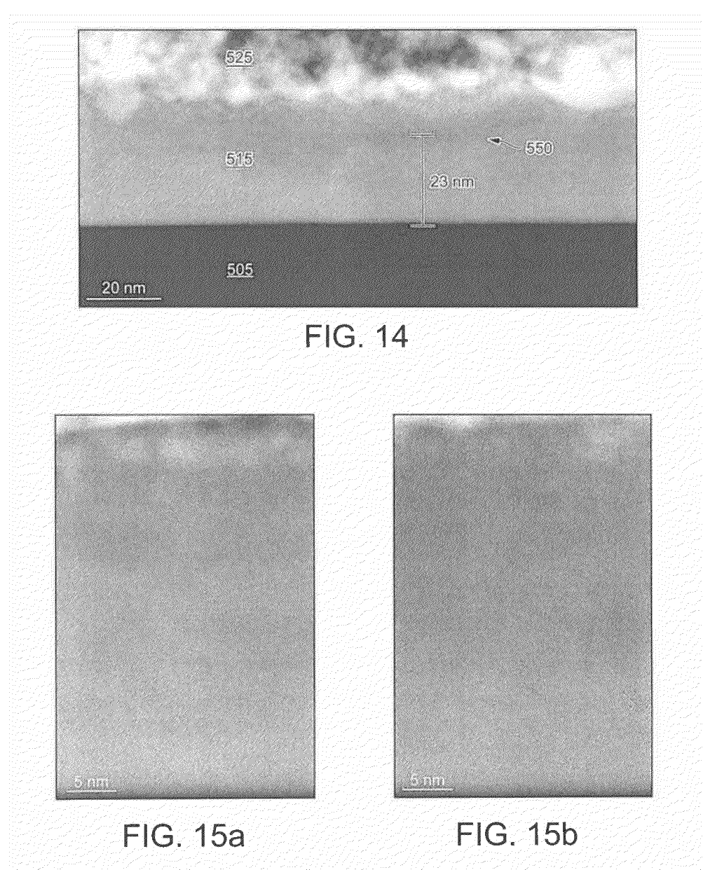

To prepare the cross-section of the films, a focussed ion beam microscope FEI Quanta single beam was used. Lamellae from a continuously grown PEALD hafnia film (FIGS. 12 and 13), and another from the interrupted PEALD sequence with a sixty minute delay (FIGS. 14, 15 and 16) having a higher dielectric constant (k), samples were obtained by Ga ion beam milling and fine polishing. These cross sections were thinned until they were transparent to electron beams. The two lift-out films were presented together on the same Omniprobe TEM support ‘grid’, which allowed the two samples to be investigated without changing the sample, i.e. altering the vacuum and electron optical conditions.

Both samples were about 10 μm wide and were thinned at the end to provide an electron transparent region. Both films could be tilted so that the silicon substrate was oriented along the [110] direction. All STEM imaging was undertaken in this condition on the assumption that the growth plane for the hafnia was (001)_{Si}.

FIG. 12 shows a TEM image of a continuous PEALD hafnium oxide coating 510 on a silicon substrate 500 with a platinum top coating 520. The hafnia film 510 is reasonably flat and uniform in contrast. The hafnia film thickness was about 36 nm with an apparently small amount of interfacial roughness at the Si—HfO₂ interface and a rougher HfO₂—Pt interface. The thin dark line at the latter suggests no significant alloying or diffusion across this boundary.

FIGS. 13a and 13b show the hafnium oxide coating 510 of FIG. 12 at higher magnification. Generally the hafnia films were polycrystalline with large grain sizes (10-30 nm) in coexistence with some random contrast suggestive of an amorphous layer too, probably due to the FIB-milling. Some crystal grains were suitably oriented to the electron beam giving string lattice contrast within each grain. The sharp drop in lattice visibility is consistent with a granular film.

FIG. 14 shows a TEM image of a discontinuous PEALD hafnium oxide coating 515 with a delay of 60 minutes on a silicon substrate 505 with a platinum top coating 525. The hafnia film thickness was again about 36 nm. The most obvious difference in this sample was a slightly darker appearance about 20 to 25 nm from the Si—HfO₂ interface. This dark region 550 is a thin dark band that is quite non-uniform across the film. In some places the darkening is strong, in others it is less so. Secondary phases were not seen, i.e. precipitates, neither were voids or pores that might form in the presence of desorbing material. The delay interrupts or intervenes with continuous growth and introduces small amount of disorder in the crystalline structure as shown by the dark band 550 seen in the TEM image.

FIGS. 15a and 15b show the hafnium oxide coating of FIG. 14 at higher magnification. Grain size was similar to that for the EPALD hafnia film i.e. 10-30 nm.

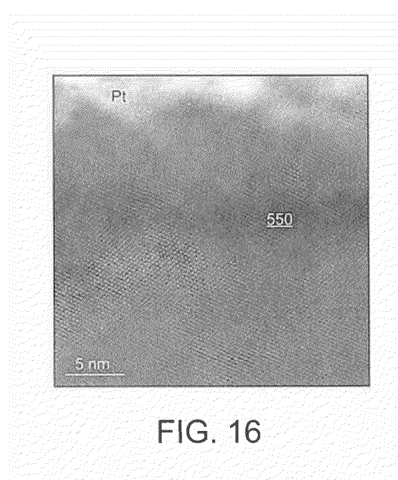

FIG. 16 shows the hafnium oxide coating of FIG. 14 at even higher magnification showing the dark grey band 550. The dark grey band indicates that there is more backscattering thus less transmission in this region caused by a crystallographic distortion believed to be formed due to the pause or delay at 200 cycles or half way through the PEALD process.

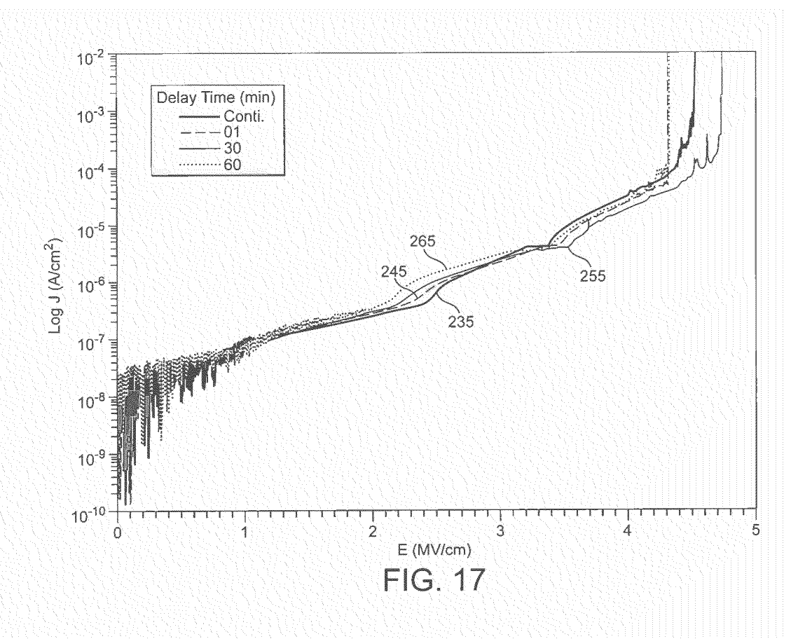

FIG. 17 shows a graph of leakage current density against electric field for PEALD produced hafnium oxide coatings to illustrate the effect of different pause lengths on the leakage current density of the hafnium oxide coating. Four different processes were carried under the conditions detailed with respect to FIGS. 1 to 3. A first continuous process 235, one with a one minute delay 245, another with a thirty minute delay 255 and a last process with a sixty minute delay 265. Each delay was conducted after 200 cycles. From the graph it can be seen that there is very little difference between the curves. This means that the increase in the dielectric constant is not due to a difference in the leakage current density of each coating. Thus the enhancement that has been found when a delay or pause is introduced is purely due to a structural modification of the coating that occurs during the delay. This structural modification can be seen visually as a dark grey band 550.

Based on the TEM analysis presented above, there is no significant change in the crystallinity between the continuous and interrupted films. There is no significant difference in the thickness of the two films. However, the interrupted film is slightly rougher than the continuously deposited film. Importantly, there were dark bands towards the centre of the interrupted film obtained in the STEM ADF. These dark bands can mean that the film is less dense in that region or that the chemical composition in that region has a higher fraction of low atomic number (Z) elements. It is most likely if the hafnia has a large number of point defects (vacancies on either the Hf or O sites). It is suggested that the hafnia film incorporates vacancies in its structure during interruption (pausing the ALD cycle). The higher k could be due to increase in polarisation centres in these point defects at the midpoint region of the film where the dark bands are visible.

In summary, it is known that HfO₂ exhibits a higher dielectric constant in the cubic (k˜29) or in the tetragonal (k˜70) structures than in a monoclinic one (k˜20). The cubic and the tetragonal phases of HfO₂ are metastable and generally require high temperature (˜2700° C.) to achieve the monoclinic to tetragonal or tetragonal to cubic phase transformation. However, the cubic and tetragonal phases of HfO₂ can be stabilised by the addition of rare earth metals. For example, Ce-doped HfO₂ showed stabilised cubic or tetragonal phase and the dielectric constant of 32 [P. R. Chalker et al., Appl. Phys. Lett. 93, 182911 (2008)]. Meanwhile, a very simple modification in ALD process as discussed above can boost the dielectric constant as much as a doping technique. Electrical results showed that the dielectric constant of the interrupted film was at least 50 percent higher, with a value of around 30, than the continuously deposited film that had a k of 20. The leakage current of the two films were in the same order of magnitude (10-8 A/cm2). Physical characterisation techniques like transmission electron microscopy and X-ray analysis were performed to understand the reasons for the change in property of the two types of films. High resolution TEM showed dark bands in middle of film corresponding to the interruption of the process. EDX analysis showed a peak in Ga signal in the midpoint region indicating diffusion into vacancies. These bands are therefore attributed to defects and morphological changes due to annealing during the interruption. X-ray analysis did not show any presence of a high k cubic phase as both the films were monoclinic. Thus the vacancy related non-uniformity in the interrupted film could be the cause for the enhancement in the dielectric constant through increased polarization centres.

Thus, adding a delay between deposition cycles in an ALD process (both thermal and plasma enhanced) leads to the formation of a high quality oxide having a higher dielectric constant than that of conventional ALD formed oxide.

1. A method of depositing a material on a substrate using an atomic layer deposition process, wherein the deposition process comprises a first deposition step, a second deposition step subsequent to the first deposition step, and a delay between the first deposition step and the second deposition step.

2. The method of claim 1, wherein the delay is for a period of time of at least one minute.

3. The method of claim 1, wherein the delay is introduced to the deposition process by maintaining constant pressure in a process chamber in which the substrate is located.

4. A method of depositing a material on a substrate using an atomic layer deposition process in a chamber, wherein the deposition process comprises a first deposition step, a second deposition step subsequent to the first deposition step, and for a period of time between the first deposition step and the second deposition step maintaining a substantially constant pressure within the chamber.

5. The method of claim 3, wherein the substantially constant pressure is maintained by maintaining a constant flow of Argon in the chamber.

6-8. (canceled)

9. The method of claim 1, wherein each deposition step comprises a plurality of deposition cycles.

10. The method of claim 9, wherein each of the deposition steps comprises at least fifty deposition cycles.

11. The method of claim 9, wherein at least one of the deposition steps comprises at least one hundred deposition cycles.

12. The method of claim 1, wherein each deposition cycle commences with the introduction to a chamber housing the substrate of a precursor for forming the material on the substrate.

13. The method of claim 12, wherein each deposition cycle ends with the introduction of the purge gas into the chamber for a second period of time which is shorter than the duration of the period of time between the first deposition step and the second deposition step.

14. A method of depositing a material on a substrate, wherein a plurality of atomic layer deposition cycles are performed on a substrate located in a process chamber to deposit the coating on the substrate, each deposition cycle comprising introducing a plurality of precursors sequentially into the chamber, and, after introducing each precursor into the chamber, introducing a purge gas to the chamber for a period of time, and wherein, for a selected one of the deposition cycles performed before a final deposition cycle, the duration of the period of time for which purge gas is supplied to the chamber immediately prior to the commencement of the subsequent deposition cycle is greater than the duration of that period of time for each of the other deposition cycles.

15. The method of claim 4, wherein the duration of said period of time is at least one minute.

16. The method of claim 4, wherein the duration of said period of time is in the range from 1 to 120 minutes.

17. The method of claim 14, wherein the selected one of the deposition cycles occurs substantially midway through the deposition process.

18-20. (canceled)

21. The method of claim 1, wherein the substrate comprises a plurality of carbon nanotubes.

22. The method of claim 1, wherein the coating comprises a dielectric material.

23. (canceled)

24. The method of claim 1, wherein the coating comprises one of hafnium oxide and titanium oxide.

25. A coated substrate made using the method of claim 1.

26. A capacitor comprising a coated substrate made using the method of claim 1.

27. (canceled)

28. The method of claim 2, wherein the delay is introduced to the deposition process by maintaining constant pressure in a process chamber in which the substrate is located.

29. The method of claim 4, wherein the substantially constant pressure is maintained by maintaining a constant flow of Argon in the chamber.

30. The method of claim 16, wherein the duration of said period of time is in the range from 10 to 90 minutes.

31. The method of claim 10, wherein at least one of the deposition steps comprises at least one hundred deposition cycles.

32. The method of claim 14, wherein the duration of said period of time is at least one minute.

33. The method of claim 14, wherein the duration of said period of time is in the range from 1 to 120 minutes.

34. The method of claim 4, wherein the substrate comprises a plurality of carbon nanotubes.

35. The method of claim 14, wherein the substrate comprises a plurality of carbon nanotubes.

36. The method of claim 4, wherein the coating comprises a dielectric material.

37. The method of claim 14, wherein the coating comprises a dielectric material.

38. The method of claim 4, wherein the coating comprises one of hafnium oxide and titanium oxide.

39. The method of claim 14, wherein the coating comprises one of hafnium oxide and titanium oxide.

40. A coated substrate made using the method of claim 4.

41. A coated substrate made using the method of claim 14.

42. A capacitor comprising a coated substrate made using the method of claim 4.

43. A capacitor comprising a coated substrate made using the method of claim 14.
